(19) United States
(12) Patent Application Publication
(10) Pub. No.: US 2013/0043578 A1
(43) Pub. Date: Feb. 21, 2013

(54) PRESSPIN, POWER SEMICONDUCTER MODULE AND SEMICONDUCTER MODULE ASSEMBLY WITH MULTIPLE POWER SEMICONDUCTER MODULES

(71) Applicant: Franc DUGAL, Zollikon (CH)

(72) Inventor: Franc DUGAL, Zollikon (CH)

(73) Assignee: ABB TECHNOLOGY AG, Zurich (CH)

(21) Appl. No.: 13/587,461

(22) Filed: Aug. 16, 2012

(30) Foreign Application Priority Data
Aug. 17, 2011 (EP) 11177800.7

(51) Int. Cl. H01L 23/32

(52) U.S. Cl. 257/690; 257/E23.002

(57) ABSTRACT

A first presspin includes a foot, whereby a base of the foot is provided for contacting a contact element of a power semiconductor device, such as within a power semiconductor module including a base plate and at least one power semiconductor device, which is arranged on the base plate and contacted by at least one further presspin. An insulation means is provided for electrically an outer surface of the foot. A power semiconductor module is also provided including a base plate, at least one power semiconductor device arranged on the base plate, and at least one of the aforementioned first presspin provided with the aforementioned insulation means. A power semiconductor module assembly is also provided including multiple power semiconductor modules as specified above, whereby the power semiconductor modules are arranged side by side to each other with electric connections between adjacent power semiconductor modules.

### RELATED APPLICATION

This application claims priority under 35 U.S.C. §119 to European Patent Application No. 11177800.7 filed in Europe on Aug. 17, 2011, the entire content of which is hereby incorporated by reference in its entirety.

### FIELD

The present disclosure relates to a presspin with a foot, whereby a base of the foot is provided for contacting a contact element of a power semiconductor device, for example, within a power semiconductor module including a base plate and at least one power semiconductor device, which is arranged on the base plate and contacted by at least one second presspin. The present disclosure also relates to a power semiconductor module including a base plate, at least one power semiconductor device, which is arranged on the base plate, and at least one first presspin for contacting at least one contact element of the at least one power semiconductor device. The present disclosure also relates to a power semiconductor module assembly including multiple power semiconductor modules.

### BACKGROUND INFORMATION

First presspins of the aforementioned kind, which are, for simplicity of description, also referred to as presspins, are known and are used in the area of contacting power semiconductor devices, such as high power semiconductor devices. In this area, high currents of at least 30 A for a normal operation mode and in case of failure in the range of 2000 A pass through the presspin, and may not affect its integrity. Each presspin includes a foot and a head, which are movable relative to each other along a longitudinal axis of the presspin and which are electrically interconnected, for example, by a current bypass. Between the foot and the head a spring element is arranged, which exerts an outwardly directed force on the foot and the head for pushing them against contact elements of the power semiconductor devices and opposed contacts, for example, a lid of a housing, to maintain electric connection therebetween. The spring element may be a spring washer pack, but other spring elements may be used as well. The contact between the foot and the respective contact element is provided via a base of the foot. Such presspins are used to contact gate or control contacts, collector contacts and/or emitter contacts.

Contact elements as mentioned above can be, for example, a top or bottom face of the power semiconductor device, depending on its arrangement, or a separate contact element provided on the base plate, for contacting a control electrode of the power semiconductor device. The control electrode may be a gate electrode, which is electrically connected by means of a wire or the like to this separate contact element. The control electrode of the power semiconductor device may be located on its top side.

For example, the bottom or collector side of the semiconductor chip can be attached by soldering, sintering or the like to the base plate, which is electrically conductive, thereby forming a surface contact. The top or emitter side of the semiconductor device can be contacted by a presspin. The separate contact element connected to the gate electrode is arranged on and electrically isolated from the base plate, and also contacted by a presspin.

These power semiconductors devices may deal with voltages of about 1.7 kV or higher. The surface contact between the semiconductor device and the base plate additionally enables heat transfer away from the semiconductor, that is, the semiconductor device is thermally and electrically coupled to the base plate. Known power semiconductor devices used in this area are power transistors like insulated gate bipolar transistors (IGBT), reverse conducting insulated gate bipolar transistors (reverse conducting IGBT), bi-mode insulated gate transistors (BIGT) or (power) diodes.

Power semiconductor devices may be combined, for example, for forming a power semiconductor module, which can deal with currents of up to 100 A or more. The power semiconductor devices are arranged in parallel on a base plate, which may form an electrically conducting base of the power semiconductor module. The power semiconductor module may be covered by an electrically conducting lid, which provides a further contact for the power semiconductor devices. The power semiconductor devices may be connected to the electrically conducting lid by means of the presspins. In the case of power transistors, the control contact is also connected to the lid, whereby the lid is isolated from the control contact.

Multiple power semiconductor modules can be further combined to form a power semiconductor module assembly. The power semiconductor modules are arranged mechanically and electrically in parallel to each other in a common housing. The base plates of the semiconductor modules form an electrically conducting base of the module assembly. Additionally, the housing of the power semiconductor module assembly is also covered by an electrically conducting lid, which is in contact with the lids of the power semiconductor modules arranged therein. The power semiconductor module assembly can include identical power semiconductor modules, for example, power semiconductor modules including power transistors, or different power semiconductor modules, for example, a set of power semiconductor modules including power transistors and at least one power semiconductor module including diodes. Such power semiconductor module assemblies are, for example, known as “Stakpak” from the applicant and can be used for forming stacked arrangements as used for example in HVDC applications, which deal with up to several hundred kV. Accordingly, the mechanical design of the power semiconductor module assembly is optimized in order to facilitate clamping in long stacks. In these stacked arrangements, care should be taken toward the mechanical and electrical stability of a single power semiconductor module assembly to prevent failures of the entire stacked arrangement.

Instead of arranging the power semiconductor modules into power semiconductor module assemblies and stacking of the power semiconductor module assemblies, the power semiconductor modules can also be stacked directly.

In this context, there should be support of a short circuit failure mode (SCFM) of the individual power semiconductor devices. In case one of the power semiconductor devices fails, it fails by providing a short circuit to enable conduction from the base plate to the lid. This refers to the power semiconductor modules as well as to the power semiconductor module assemblies, which are disabled in SCFM. When multiple of the power semiconductor modules or the power semiconductor module assemblies are connected in series, for example, forming the above-mentioned stacked arrangement, failure of a single power semiconductor device does not lead to a failure of the series of the power semiconductor modules or the power semiconductor module assemblies.

Especially in this short circuit failure mode, very high currents of up to 2000 A can flow through a single power semiconductor device and the respective presspin in contact with the failing power semiconductor device, since the short circuit bridges all parallel power semiconductor devices. To achieve a high life time of these power semiconductor devices and accordingly a high life time of the power semiconductor modules and the power semiconductor module assemblies, it is desired that the short circuit failure mode can be maintained for a year or even more.

Due to the high currents in SCFM, the quality of the electric connection between the contact element and the foot of the presspin can reduce over the time. Arcing between the presspin in contact with the power semiconductor device in SCFM and other presspins can occur. Accordingly, the contact element and the foot of the presspin underlie wearing and oxidation, thereby increasing the resistance of the electric connection there between, which reduces the short circuit capabilities in SCFM. Electrical arcing can even lead to consumption of the entire presspin in contact with the power semiconductor device in SCFM. The arcing can also propagate to other presspins, until all of them are entirely consumed, or in other words destroyed. This would result in a failure of the power semiconductor module and accordingly of the power semiconductor module assembly including the power semiconductor device in SCFM. When a presspin is consumed, its spring washer pack is not able to maintain electric contact between the contact element and the lid as required for operation of the power semiconductor module.

The drawback of arcing and pin consumption also refers to presspins, which are not carrying the load current, and which were therefore thought to be suitable to maintain the mechanical stability of the power semiconductor modules and the power semiconductor module assemblies. This particularly refers to gate contacts of the power semiconductor devices, which do not carry the load current during SCFM and therefore are used in a power semiconductor module to maintain its mechanical stability. Accordingly, presspins contacting the gate should never been consumed. Therefore, it is important to prevent electrical arcing at these presspins, especially in short circuit failure mode.

In the art, the propagation of electrical arcing is intended to be solved by a proper design of power semiconductor modules. Nevertheless, it has turned out that even when placing individual presspins at large distances apart from each other, electrical arcing and consumption of the presspins cannot reliably be prevented. Even presspins contacting the control contact can still be affected by the electrical arcing.

### SUMMARY

An exemplary embodiment of the present disclosure provides a power semiconductor module which includes a base plate, at least one power semiconductor device which is arranged on the base plate, and at least one first presspin including a first foot and a first head. The first foot and the first head are movable relative to each other along a longitudinal axis of the at least one first presspin, and the first foot and the first head are electrically interconnected. The exemplary power semiconductor module also includes a spring element arranged between the first foot and the first head of the at least one first presspin and configured to exert an outwardly directed force on the first foot and the first head. The at least one first presspin is configured to contact at least one contact element with a base of the first foot. In addition, the at least one first presspin includes an insulation means having a tubular body for electrically isolating an outer surface of the first foot of the at least one first presspin.

### BRIEF DESCRIPTION OF THE DRAWINGS

Additional refinements, advantages and features of the present disclosure are described in more detail below with reference to exemplary embodiments illustrated in the drawing, in which:

FIG. 1 shows a partial sectional view of a power semiconductor module with a power semiconductor device and first and second presspin contacting contact elements of the power semiconductor device, according to an exemplary embodiment of the present disclosure.

### DETAILED DESCRIPTION

Exemplary embodiments of the present disclosure provide a power semiconductor module including a first presspin that provides a good electrical and mechanical stability and has a long life-time, even in the presence of electrical arcing. Exemplary embodiments of the present disclosure also provide a power semiconductor module arrangement, which has an increased life-time, especially when operating in short circuit failure mode.

An exemplary embodiment of the present disclosure provides a power semiconductor module including a first presspin with a foot, whereby a base of the foot is provided for contacting a contact element of a power semiconductor device, for example, within a power semiconductor module including a base plate and at least one power semiconductor device, which is arranged on the base plate. An insulation means is provided for electrically isolating an outer surface of the foot. The power semiconductor device may be contacted by at least one further presspin.

An exemplary embodiment of the present disclosure also provides a power semiconductor module assembly which includes multiple power semiconductor modules as specified above, whereby the power semiconductor modules are arranged side by side to each other with electric connections between adjacent power semiconductor modules.

An underlying feature of the present disclosure is to electrically isolate and protect the outer surface of the foot of the presspin with an isolation means. On the one hand, the insulation means prevent the appearance of electrical arcing at a first presspin, which may carry a high load current, for example, in short circuit failure mode (SCFM). On the other hand, the insulation means prevents first presspins, which are not carrying a high load current, from being consumed due to electrical arcing originated at a further presspin. The further presspin can be another first presspin or a second presspin, which is a presspin known in the art. The isolating means provide good electrical isolation capabilities, so that they can effectively reduce the appearance of electrical arcing and the consumption of first presspins due to electrical arcing. Since electrical arcing can never completely be eliminated, the insulation means also has a high melting temperature, so that it maintains the insulation capabilities for a long time. Since the temperature around electrical arcing can reach a few hundred degrees Celsius, the melting temperature of the insulating means may be higher than the temperature caused by electrical arcing. A power semiconductor module having at least one first presspin will have an increased life-time, since the insulation means reduces the consumption of the first presspin and the power semiconductor module can be operated for a prolonged period of time in short circuit failure mode. Also, the mechanical stability of the power semiconductor module will be maintained for a prolonged period of time, since the consumption of the first presspin is reduced. By reducing arcing at the first presspin carrying a high load current, for example, in SCFM, the lifetime of other first and second presspins in the power semiconductor module is also increased. Accordingly, the power semiconductor module as well as the power semiconductor module assembly can be operated for a prolonged time before failure occurs and replacement is required. This also increases the lifetime and reduces maintenance intervals of stacked arrangements of power semiconductor modules as well as the power semiconductor module assemblies.

According to an exemplary embodiment of the present disclosure, the insulation means is provided having a tubular body, which is arranged to surround the foot. The cross shape of the tubular body may be adapted to the cross shape of the foot. A circular cross shape is one exemplary configuration. The tubular body can easily be mounted to the foot of the first presspin providing insulation over its entire circumference.

According to an exemplary embodiment of the present disclosure, the tubular body has a thickness of 0.5 mm to 2.0 mm. This thickness is most suitable for today's common first presspins. Depending on the particular design of the first presspin and the involved currents, the thickness may also be bigger or smaller.

According to an exemplary embodiment of the present disclosure, the insulation means extends over the entire height of the foot. In this manner, the entire foot is insulated and electrical arcing is best prevented.

According to an exemplary embodiment of the disclosure, the insulating means includes a ceramic base material. For example, the insulation means can be made entirely of the ceramic base material. The ceramic base material provides good insulation capabilities and has a high melting temperature.

In an exemplary embodiment of the present disclosure, the ceramic base material is Al₂O₃, which is also known as alumina. Alumina is a well-known ceramic material, which provides good insulation capabilities and has a high melting temperature.

In an exemplary embodiment of the power semiconductor module of the present disclosure, at least one second presspin is provided for contacting at least one contact element of the one or multiple power semiconductor devices. Accordingly, first and second presspins can be combined in the power semiconductor module to keep it simple and cheap. To maintain mechanical stability of the power semiconductor module, it is only required to protect some of the presspins, for example, the first presspins.

According to an exemplary embodiment of the power semiconductor module of the present disclosure, at least one power semiconductor devices is an insulated gate bipolar transistor, a reverse conducting insulated gate bipolar transistor, a bi-mode insulated gate transistor, or a diode. These power semiconductor devices are suitable for being operated in high power conditions and can deal with high voltages and currents. In accordance with an exemplary embodiment, multiple identical power semiconductor devices are combined in a single power semiconductor module. Alternatively, an arbitrary set of power semiconductor devices from the listed power semiconductor devices is combined in a single power semiconductor module.

According to an exemplary embodiment of the power semiconductor module of the present disclosure, the power semiconductor module includes multiple power semiconductor devices with at least one contact element provided as a common control contact of the multiple power semiconductor devices, and a first presspin is in contact with the least one contact element provided as the common control contact. Control contacts only have to deal with relatively small currents, so that they can easily be combined. This allows providing a contact element with a surface sufficiently big for being contacted by standard first or second presspins without occupying too much space on the base plate. This allows an efficient design of the power semiconductor module. Also, first or second presspins with unique dimensions can be used for contacting all contact elements of the power semiconductor devices. The common control contact is placed on the base plate, but not in electrical contact with the base plate. In accordance with an exemplary embodiment, an insulating layer is provided between the common control contact and the base plate.

According to an exemplary embodiment of the power semiconductor module of the present disclosure, the power semiconductor module includes a housing, whereby an electrically conducting lid forms a top side of the housing and provides a first contact of the power semiconductor module, the base plate forms a base of the housing and provides a second contact of the power semiconductor module, a first contact of the at least one power semiconductor device is in electric contact with the lid via a first or second presspin, and a control contact of the at least one power semiconductor device is in contact with the lid via a first presspin. In accordance with an exemplary embodiment, first or second presspins are provided between the semiconductor devices and the lid for providing the electrical contact. Generally speaking, the lid provides a common first contact of the power semiconductor module for contacting the first contacts of the power semiconductor devices, and the base plate provides a second contact of the power semiconductor module. The first and second contacts of the power semiconductor module can be contacted by other power semiconductor modules in the case of a stacked arrangement or by respective contacts of a power semiconductor module assembly. In the case of power transistors like IGBTs, the first contact refers to an emitter contact, the second contact refers the collector contact, and the control contact refers to a gate contact. The control contact is not in electric contact with the lid of the power semiconductor module and can be contacted for example, through a gap in the lid or by a lateral contact of the power semiconductor module.

According to an exemplary embodiment of the power semiconductor module assembly of the present disclosure, the base plates of the power semiconductor modules are electrically connected to each other. The connection can be made by wiring or by providing a contact plate for contacting the base plates and/or the lids of the semiconductor modules. The first contacts and/or the second contacts of the power semiconductor modules accordingly form a common first and/or second contact of the power semiconductor module assembly. In case of the power semiconductor modules containing at least one power transistor, the control contact can be electrically connected.

According to an exemplary embodiment of the power semiconductor module assembly of the present disclosure, the power semiconductor module assembly includes a housing, whereby an electrically conducting lid forms a top side of the housing and provides a first contact of the power semiconductor module assembly, which is in contact with the first contacts of the power semiconductor modules, and the base plates of the power semiconductor modules extend through a base of the housing. The first and second contacts of the power semiconductor module assembly can be contacted by other power semiconductor module assemblies in the case of a stacked arrangement. Generally speaking, the lid of the power semiconductor module assembly provides a first contact for contacting the first contacts of the power semiconductor modules, and the base plates of the power semiconductor modules provide a common second contact of the power semiconductor modules. In case the power semiconductor modules have control contacts, they can also be electrically connected within the power semiconductor module assembly. The power semiconductor module assembly can have a lateral contact for contacting the connected control contacts of the power semiconductor modules, or the connected control contacts of the power semiconductor modules can be contacted through a gap in the lid. The first and second contact of the power semiconductor module assembly can be contacted by other power semiconductor module assemblies in the case of a stacked arrangement. In the case of power transistors like IGBTs, the first contact refers to an emitter contact, the second contact refers to a collector contact, and the control contact refers to a gate contact.

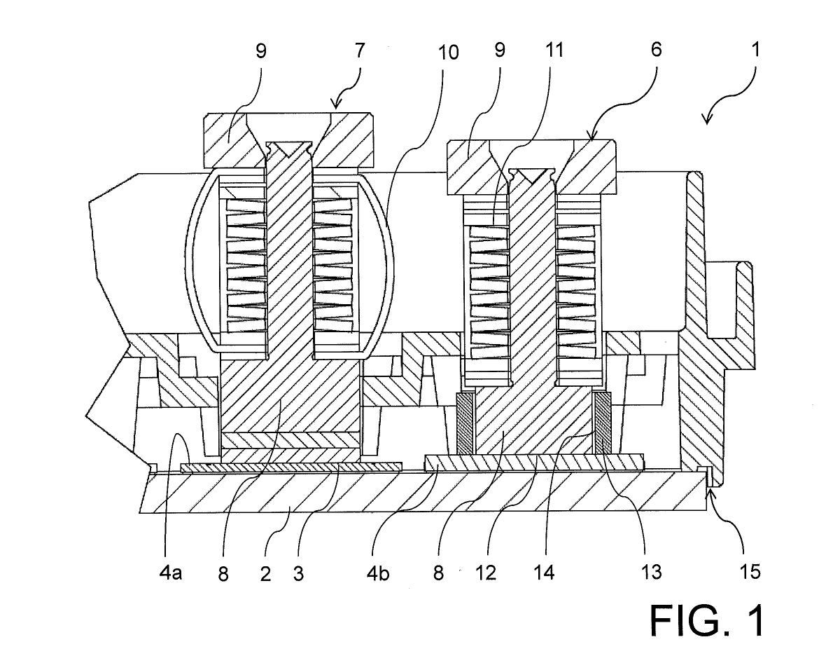

FIG. 1 shows a part of a power semiconductor module 1 according to an exemplary embodiment of the present disclosure. The power semiconductor module 1 includes an electrically conducting base plate 2 and a power semiconductor device 3, which is arranged on the base plate 2. The top side 4a of the semiconductor device 3 forms a first contact thereof, which is a first contact element according to the present disclosure. A second contact of the power semiconductor device 3 is formed at its bottom side, which is in electric contact with the base plate 2. A control contact of the power semiconductor device 3 is connected to a separate contact element 4b, which is another contact element for the power semiconductor device 3 according to the present disclosure. The separate contact element 4b is also referred to as a control contact. The separate contact element 4b is provided with a planar shape on the base plate 2, but is electrically insulated from the base plate 2 by an insulating layer, which is not visible in the drawing.

The power semiconductor device 3 in this embodiment of the present disclosure is an insulated gate bipolar transistor (IGBT). In accordance with this example, the first contact is an emitter contact, the second contact is a collector contact and the control contact is a gate contact. Accordingly, the separate contact element 4b is connected to the gate contact is also referred to as gate runner.

The gate runner 4b is contacted by a gate pin 6, which is a first presspin according to the present disclosure. The top side 4a of the power semiconductor device 3 is contacted by a chip pin 7, which is a second presspin according to the present disclosure. The gate pin 6 as well as the chip pin 7 each include a foot 8 and a head 9, which are in electrical contact, for example by a current bypass 10, and a spring washer pack 11 exerting an outwardly directed force on the foot 8 and the head 9. Instead of the spring washer pack, another spring element may be used.

Now referring to the first press pin 6, i.e. the gate pin 6, its foot 8 has an end face as a base 12, which is in electric contact with the gate runner 4b. According to an exemplary embodiment of the present disclosure, an insulation means 13 is provided around the outer surface 14 of the foot 8 for providing an electric isolation. The insulation means 13 has a tubular body, which is arranged to surround the foot 8. The tubular body of the insulating means 13 extends over the entire height of the foot 8. In this embodiment of the present disclosure, the tubular body has a thickness of approx. 1.0 mm, although in different embodiments of the disclosure, the thickness can vary, for example, between 0.5 mm and 2.0 mm. The insulation means 13 are made of a ceramic base material. In accordance with an exemplary embodiment of the present disclosure, the ceramic base material may be made of alumina, also known as Al₂O₃.

Although not explicitly shown in FIG. 1, the power semiconductor module 1 includes multiple of the afore-described power semiconductor devices 3. The top side 4a of each power semiconductor device 3 is contacted by a respective chip pin 7. The control electrodes of the power semiconductor devices 3 are connected to one or more than one common contact element, i.e. the gate runner 4b as described above, which is contacted by the gate pin 6 as described above. In case more than one common contact element is used, each contact element is contacted by a respective gate pin 6. Accordingly, the power semiconductor module 1 is formed with multiple power semiconductor devices 3 arranged in parallel to each other. In case diodes are used in addition to controllable power semiconductor devices 3, they are arranged anti-parallel.

The power semiconductor module 1 includes a housing 15, whereby the base plate 2 forms a base of the housing 15. An electrically conducting lid forms a top side of the housing 15. The lid provides a first contact of the power semiconductor module 1, and the base plate 2 provides a second contact of the power semiconductor module 1. The power semiconductor devices 3 are in electric contact with the lid by means of first and second presspins 6, 7, which are provided between the contact elements 4a, 4b of the power semiconductor devices 3 and the lid. The base plate 2 is connected to the collectors of the power semiconductor devices 3 and forms a second contact of the power semiconductor module 1, and the emitters of the power semiconductor devices 3 are connected to the lid. The gates of the power semiconductor devices 3 can be commonly contacted in the power semiconductor module 1 through a gap in the lid.

In accordance with an exemplary embodiment of the present disclosure, a power semiconductor module assembly includes multiple power semiconductor modules as described above. The power semiconductor modules 1 are arranged side by side to each other within a housing, whereby the base plates 2 of the power semiconductor modules 1 extend through a base of the housing. An electrically conducting lid forms a top side of the housing and provides a common contact for the power semiconductor modules 1 with electric connections between adjacent power semiconductor modules 1. The lid provides a first contact of the power semiconductor module assembly for contacting the first contacts of the power semiconductor modules 1 and the base plates 2 commonly provide a second contact of the power semiconductor module assembly. The control contacts of the power semiconductor modules 1 are connected to each other within the power semiconductor module assembly and to a lateral electric contact of the power semiconductor module assembly.

The power semiconductor module assembly includes different semiconductor modules. In this exemplary embodiment of the disclosure, the different semiconductor modules include a set of power semiconductor modules 1 including power transistors and at least one power semiconductor module comprising diodes.

The power semiconductor modules 1 as well as the power semiconductor module assemblies can be stacked.

While the disclosure has been illustrated and described in detail in the drawings and foregoing description, such illustration and description are to be considered illustrative or exemplary and not restrictive; the disclosure is not limited to the disclosed embodiments. Other variations to be disclosed embodiments can be understood and effected by those skilled in the art in practicing the claimed disclosure, from a study of the drawings, the disclosure, and the appended claims. In the claims, the word “comprising” or “including” does not exclude other elements or steps, and the indefinite article “a” or “an” does not exclude a plurality. The mere fact that certain measures are recited in mutually different dependent claims does not indicate that a combination of these measures cannot be used to advantage.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### REFERENCE SIGNS LIST

1 power semiconductor module
2 base plate
3 power semiconductor device
4a contact element, top side of power semiconductor device
4b contact element, gate runner, common control contact
6 first presspin, gate pin
7 second presspin, chip pin
8 foot
9 head
10 current bypass
11 spring washer pack
12 base, end face
13 insulation means
14 outer surface
15 housing

What is claimed is:

1. A power semiconductor module comprising:
a base plate;
at least one power semiconductor device which is arranged on the base plate;
at least one first presspin including a first foot and a first head, the first foot and the first head being movable relative to each other along a longitudinal axis of the at least one first presspin, and the first foot and the first head being electrically interconnected; and
a spring element arranged between the first foot and the first head of the at least one first presspin and configured to exert an outwardly directed force on the first foot and the first head, wherein:
the least one first presspin is configured to contact at least one contact element with a base of the first foot; and
the at least one first presspin includes an insulation means having a tubular body for electrically isolating an outer surface of the first foot of the at least one first presspin.

2. The power semiconductor module according to claim 1, wherein the insulation means is arranged to surround the first foot.

3. The power semiconductor module according to claim 1, wherein the tubular body has a thickness of 0.5 mm to 2.0 mm.

4. The power semiconductor module according to claim 1, wherein the insulation means extends over the entire height of the first foot.

5. The power semiconductor module according to claim 1, wherein the insulation means includes a ceramic base material.

6. The power semiconductor module according to claim 5, wherein the ceramic base material is comprised of Al₂O₃.

7. The power semiconductor module according to claim 1, comprising:
at least one second presspin configured to contact at least one contact element of the at least one power semiconductor device, wherein:
the second presspin includes a second foot and a second head, the second foot and the second head of the at least one second presspin being movable relative to each other along a longitudinal axis of the at least one second presspin, and the second foot and the second head of the at least one second presspin being electrically interconnected; and
the power semiconductor module comprises a spring element arranged between the second foot and the second head and configured to exert an outwardly directed force on the second foot and the second head.

8. The power semiconductor module according to claim 1, wherein the at least one power semiconductor device is one of an insulated gate bipolar transistor, a reverse conducting insulated gate bipolar transistor, a bi-mode insulated gate transistor, and a diode.

9. The power semiconductor module according to claim 1, wherein:
the power semiconductor module includes multiple power semiconductor devices with at least one contact element provided as a common control contact of the multiple power semiconductor devices; and
the at least one first presspin is in contact with the least one contact element provided as the common control contact.

10. The power semiconductor module according to claim 9, wherein the common control contact is provided on the base plate.

11. The power semiconductor module according to claim 1, comprising:
a housing;
an electrically conducting lid forming a top side of the housing and providing a first contact of the power semiconductor module, wherein:
the base plate forms a base of the housing and provides a second contact of the power semiconductor module;
a first contact of the at least one power semiconductor device is in electric contact with the lid via one of the at least one first presspin and a second presspin; and
a control contact of the at least one power semiconductor device is in contact with the lid via a first presspin.

12. A power semiconductor module assembly comprising multiple power semiconductor modules according to claim 1, wherein the power semiconductor modules are arranged side by side to each other with electric connections between adjacent power semiconductor modules.

13. The power semiconductor module assembly according to claim 12, wherein the respective base plates of the power semiconductor modules are electrically connected to each other.

14. The power semiconductor module assembly according to claim 12, comprising:
a housing; and
an electrically conducting lid forming a top side of the housing and providing a first contact of the power semiconductor module assembly, the lid being in contact with the respective first contacts of the power semiconductor modules,
wherein the respective base plates of the power semiconductor modules extend through a base of the housing.

15. The power semiconductor module according to claim 2, wherein the tubular body has a thickness of 0.5 mm to 2.0 mm.

16. The power semiconductor module according to claim 2, wherein the insulation means extends over the entire height of the foot.

17. The power semiconductor module according to claim 7, wherein the at least one power semiconductor device is one of an insulated gate bipolar transistor, a reverse conducting insulated gate bipolar transistor, a bi-mode insulated gate transistor, and a diode.

18. The power semiconductor module according to claim 7, wherein:
the power semiconductor module includes multiple power semiconductor devices with at least one contact element provided as a common control contact of the multiple power semiconductor devices; and
the at least one first presspin is in contact with the least one contact element provided as the common control contact.

19. The power semiconductor module according to claim 18, wherein the common control contact is provided on the base plate.

20. The power semiconductor module according to claim 7, comprising:
a housing;
an electrically conducting lid forming a top side of the housing and providing a first contact of the power semiconductor module, wherein:
the base plate forms a base of the housing and provides a second contact of the power semiconductor module;
a first contact of the at least one power semiconductor device is in electric contact with the lid via one of the at least one first presspin and the at least one second presspin; and
a control contact of the at least one power semiconductor device is in contact with the lid via a first presspin.

21. A power semiconductor module assembly comprising multiple power semiconductor modules according to claim 7, wherein the power semiconductor modules are arranged side by side to each other with electric connections between adjacent power semiconductor modules.

22. The power semiconductor module assembly according to claim 21, wherein the respective base plates of the power semiconductor modules are electrically connected to each other.

23. The power semiconductor module assembly according to claim 22, comprising:
a housing; and
an electrically conducting lid forming a top side of the housing and providing a first contact of the power semiconductor module assembly, the lid being in contact with the respective first contacts of the power semiconductor modules,
wherein the respective base plates of the power semiconductor modules extend through a base of the housing.

24. A power semiconductor module assembly comprising multiple power semiconductor modules according to claim 11, wherein the power semiconductor modules are arranged side by side to each other with electric connections between adjacent power semiconductor modules.

25. The power semiconductor module assembly according to claim 24, wherein the respective base plates of the power semiconductor modules are electrically connected to each other.

26. The power semiconductor module assembly according to claim 25, comprising:
a housing; and
an electrically conducting lid forming a top side of the housing and providing a first contact of the power semiconductor module assembly, the lid being in contact with the respective first contacts of the power semiconductor modules,
wherein the respective base plates of the power semiconductor modules extend through a base of the housing.
